(19) United States
(12) Patent Application Publication
(10) Pub. No.: US 2006/0038576 A1
(43) Pub. Date: Feb. 23, 2006

(54) Sort interface unit having probe capacitors

(76) Inventor: Pooya Tadayon, Hillsboro, OR (US)

Correspondence Address: INTEL CORPORATION, P.O. BOX 5326, SANTA CLARA, CA, 95056-5326, US

(21) Appl. No.: 10/922,323

(22) Filed: Aug. 19, 2004

(51) Int. Cl. G01R 31/02

(52) U.S. Cl. 324/761

(57) ABSTRACT

Briefly, in accordance with one embodiment of the invention, a sort interface unit of a wafer tester may include a micro-electromechanical system (MEMS) capacitor disposed between selected pairs of the probe tips of the sort interface unit, for example between power and ground probes. In one embodiment, the MEMS capacitor may be disposed at the ends of the probe tips nearer the wafer when the wafer is tested by the wafer tester. In another embodiment, a first capacitor having a higher value may be used for higher power circuits on the wafer, and a second capacitor having a lower value may be used for lower power circuits on the wafer. In such an arrangement, the capacitors on the probes of the sort interface unit may be selected according to a spatial power distribution of the power of the circuit or circuits on the wafer.

### BACKGROUND OF THE INVENTION

The present invention relates generally to a sort interface unit used to test and sort semiconductor wafers. In particular, the invention relates to a sort interface unit having a capacitor, such as a micro-electromechanical system (MEMS) capacitor, disposed at the probe tips of the sort interface unit.

### DESCRIPTION OF THE DRAWING FIGURES

The subject matter regarded as the invention is particularly pointed out and distinctly claimed in the concluding portion of the specification. The invention, however, both as to organization and method of operation, together with objects, features, and advantages thereof, may best be understood by reference to the following detailed description when read with the accompanying drawings in which:

FIG. 1 is a diagram of a test system to test a semiconductor wafer in accordance with one embodiment of the present invention;

FIG. 2 is a diagram of a sort interface unit in accordance with one embodiment of the present invention;

FIG. 3 is a diagram of a die, device under test (DUT), or a semiconductor chip to be tested in accordance with one embodiment of the present invention;

FIG. 4 is a schematic diagram of a sort interface unit in accordance with an embodiment of the present invention;

FIG. 5 is a diagram of a space transformer with two probes having a capacitor disposed at the tips of the probes of in accordance with an embodiment of the present invention;

FIG. 6 is a diagram of a space transformer having an array of probes thereon in accordance with an embodiment of the present invention;

FIG. 7 is a diagram of a semiconductor wafer having MEMS capacitors formed thereon in accordance with an embodiment of the present invention;

FIG. 8 is a diagram of a space transformer and array of probes ready for connection of MEMS capacitors to the end of the probes in accordance with an embodiment of the present invention;

FIG. 9 is a diagram of a space transformer and array of probes in a state after attachment of a MEMS capacitor to the end of the probes in accordance with an embodiment of the present invention;

FIG. 10 is a diagram of a space transformer and array of probes during attachment of the probe tips in accordance with an embodiment of the present invention; and

FIG. 11 is a diagram of a MEMS capacitor in accordance with an embodiment of the present invention.

It will be appreciated that for simplicity and clarity of illustration, elements illustrated in the figures have not necessarily been drawn to scale. For example, the dimensions of some of the elements are exaggerated relative to other elements for clarity. Further, where considered appropriate, reference numerals have been repeated among the figures to indicate corresponding or analogous elements.

### DETAILED DESCRIPTION

In the following detailed description, numerous specific details are set forth in order to provide a thorough understanding of the invention. However, it will be understood by those skilled in the art that the present invention may be practiced without these specific details. In other instances, well-known methods, procedures, components and circuits have not been described in detail so as not to obscure the present invention.

In the following description and claims, the terms coupled and connected, along with their derivatives, may be used. In particular embodiments, connected may be used to indicate that two or more elements are in direct physical or electrical contact with each other. Coupled may mean that two or more elements are in direct physical or electrical contact. However, coupled may also mean that two or more elements may not be in direct contact with each other, but yet may still cooperate or interact with each other.

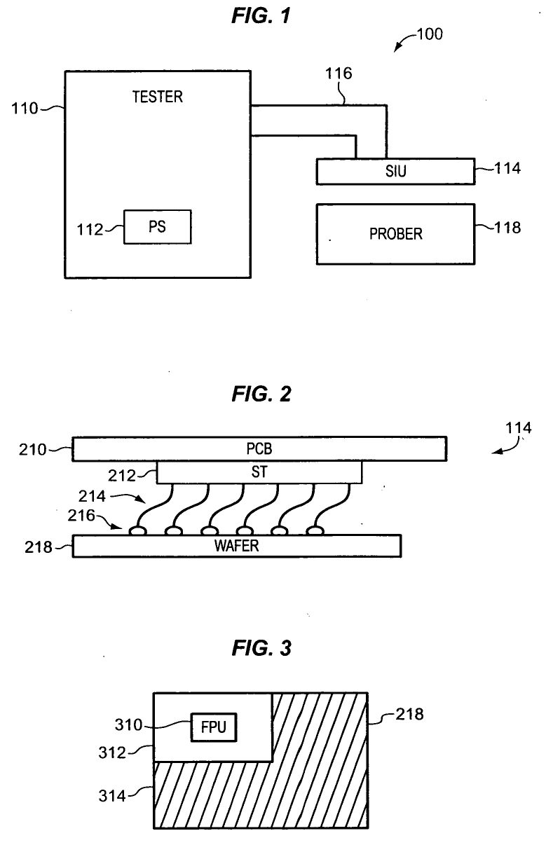

Referring now to FIG. 1, a test system to test a semiconductor wafer in accordance with one embodiment of the present invention will be discussed. The test system 100 may include a tester 110 that may be powered by a power supply (PS) 112 which may provide power to a sort interface unit 114 disposed at the an end of an arm 116 that is extended from the tester 100. Sort interface unit 114 may also be referred to as a probe card, although the scope of the invention is not limited in this respect. Sort interface unit 114 may be utilized to power and test a semiconductor wafer disposed on the prober 118 where the semiconductor wafer may have one or more DUTs formed thereon. In general, sort interface unit 114 makes electrical contact with one or more DUTs on a wafer disposed on prober 118 to test one or more characteristics of the DUT to determine process variation that may be present on the wafers due to variation during the manufacturing process. For example, tester 100 may provide power to one or more DUT via sort interface unit 114 and determine a maximum frequency characteristic exhibited by the one or more DUT. The maximum frequency characteristic, along with numerous other characteristics not described here, may be influenced by the power delivery capability of the sort interface unit. One metric used to assess the power delivery capability of the sort interface unit is referred to as voltage droop (Vdroop). The voltage droop may be influenced by a current draw of a circuit disposed on the DUT and may be a factor in determining which DUTs are within a predetermined tolerance and which are not. In addition, a given wafer may exhibit two or more characteristics that are dependent on the sort interface unit voltage droop, such as maximum frequency and leakage current, where each characteristic has a predetermined tolerance. In such an embodiment, tester 110 through sort interface unit may determine which DUTs may have multiple characteristics that meet the multiple predetermined tolerances and accordingly select which of the DUTs should be selected to be packaged into an end product, although the scope of the invention is not limited in this respect.

Referring now to FIG. 2, a diagram of a sort interface unit in accordance with one embodiment of the present invention will be discussed. A sort interface unit 114 may include a printed circuit board (PCB) 210 with a pattern of conductive traces to couple to tester 110. Printed circuit board 210 may couple to a space transformer 212 having one or more probes 214 to couple the conductive traces of PCB 210 to one or more circuits disposed on DUT 218. The probes 214 may have probe tips 216 disposed on the ends thereof to make physical and electrical contact with selected portions of the circuits disposed on DUT 218. This arrangement allows tester 110 to provide power and test signals to the circuits on DUT 218 and determine the operational characteristics thereof.

Referring now to FIG. 3, a diagram of a DUT to be tested in accordance with one embodiment of the present invention will be discussed. DUT 218 may have formed thereon one or more circuits or sub-circuits that together provide the function of DUT 218. For example, DUT 218 may be a processor where the processor may include one or more processor sub-circuits. A first region of DUT 218 may include a floating point unit 310 disposed on DUT 218. Another region 312 may include cache memory circuits 312 disposed on DUT 218, and yet another region 314 may include other circuits or sub-circuits of a processor disposed on DUT 218, for example an arithmetic logic unit (ALU), although the scope of the invention is not limited in this respect. The regions of DUT 218 may respond differently and have a different tolerance to voltage droop. For example, the low-power cache region of the DUT 218 will draw less current and as a result the voltage droop in that section will be less than the voltage droop in the floating point unit which is considered to be the high-power region of the DUT 218 that draws high current.

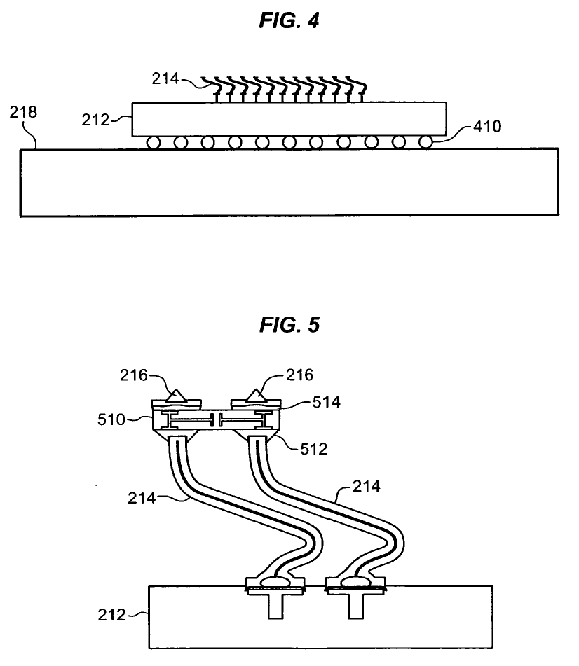

Referring now to FIG. 4, a schematic diagram of a sort interface unit in accordance with one embodiment of the invention will be discussed. In particular, FIG. 4 shows that in a sort interface unit 114 in accordance with one embodiment of the present invention, a space transformer 212 of sort interface unit 114 may be electrically coupled to printed circuit board 218 via a ball grid array 410. In an alternative embodiment, space transformer 212 of sort interface unit 114 may be electrically coupled to printed circuit board 218 via an interposer (not shown). The function of the space transformer 212 is to physically fan-out traces disposed on a circuit of a DUT 218 to a larger pitch of the traces on the printed circuit board 218 so that the traces on the DUT 218 may be coupled to tester 110 via probes 214 via space transformer through printed circuit board 218. In such an arrangement, probes 214 make electrical contact with the device under test 218, and printed circuit board 218 makes electrical contact with tester 110, although the scope of the invention is not limited in this respect.

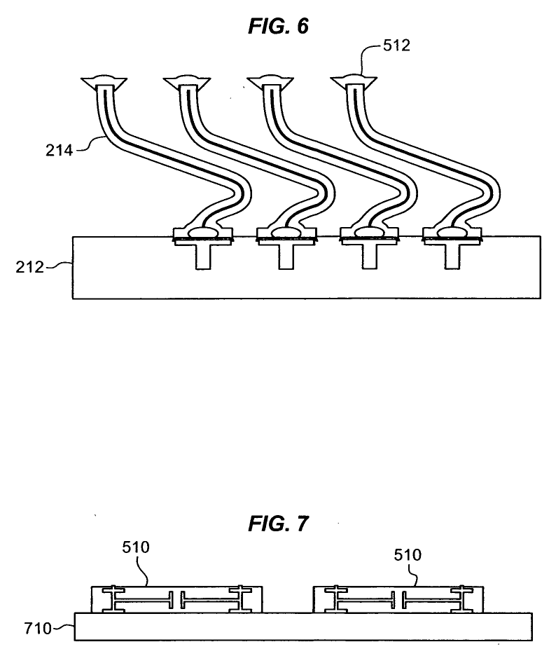

Referring now to FIG. 5, a diagram of a space transformer having a capacitor disposed at the tips of probes of the sort interface unit in accordance with one embodiment of the present invention will be discussed. In one embodiment of the invention, a capacitor 510 may be disposed between two or more of probes 214, and in one particular embodiment, capacitor 510 may be a micro-electromechanical system (MEMS) capacitor, although the scope of the invention is not limited in this respect. In a particular embodiment, capacitor 510 may be a MEMS capacitor that may be manufactured using the same process as used to form and attach probe tips 216, although the scope of the invention is not limited in this respect. In such a process, capacitor 510 may be first soldered onto the ends of probes 214 which may be prepared with solder paste 512. Probe tips 216 may be then soldered on a top surface of capacitor 510. FIG. 5 shows two adjacent probes 214 where one of probes 214 may be for power and the other one of probes 214 may be for ground. Probes 214, which in one embodiment may be micro-springs, may be obtained for example from FormFactor Inc. of Livermore, Calif., U.S.A. Probe tips 216 may be manufactured on a silicon wafer using standard lithography and plating processes. The wafer on which probe tips are formed is then flipped over, aligned with probes 214 and capacitor 510 that are already attached to space transformer 212, and then soldered onto capacitor 510, although the scope of the invention is not limited in this respect. Further details of a process for manufacturing sort interface unit 114 having one or more capacitors 510 coupled to probes 214 and probe tips follow in FIG. 6 through FIG. 11.

In accordance with one embodiment of the present invention, a sort interface unit 114 may include MEMS capacitors 510 at the ends of probes 214 at the probe tips 216 to address voltage droop. Power delivery at wafer sort, may be expressed in terms of the voltage droop (Vdroop), which is influenced by the current drawn by the device under test 218. With all other factors being the same, a higher current draw may result in a higher Vdroop. Meeting the Vdroop targets for each generation of semiconductor devices, for example processors, is becoming more and more difficult as such devices become more powerful and draw more current. In accordance with the present invention, in order to address voltage droop, capacitors 510 are placed on 214 probes, and as close possible to the device under test 218. By placing capacitors 510 near the device under test, compensation may be provided for the path inductance without requiring a reduction in the thickness of space transformer 212 or without requiring a reduction in the length of probes 214. Thus, the same basic architecture of sort interface unit 114 in general may be utilized.

Furthermore, the sort interface unit 114 of the present invention allows selective placement of more capacitance in some areas of the array of probes 214 than in other areas of the array of probes 214. For example, a processor as shown in FIG. 3 may exhibit a non-uniform spatial power distribution in that some areas of the die may draw more current and more power than other areas, for example floating point unit 310 may draw more current and power 310 than cache 312, and as a result there may be a larger voltage droop at region 310 than in region 312. In accordance with one embodiment of the invention, capacitors 510 having a higher capacitance value may be placed on probes 214 that contact higher power regions of DUT 218, for example at floating point unit 310, and capacitors 510 having a lower capacitance value may be placed on probes 314 that contact lower power regions of DUT 218, for example at cache 312, although the scope of the invention is not limited in this respect. Thus, the capacitance of capacitors 510 disposed on probes 214 may be selected according to a characteristic of the region on DUT 218 which probes 214 may contact, for example, based on current, power, voltage, and so on, although the scope of the invention is not limited in this respect.

In one particular embodiment of the invention, capacitors 510 may be MEMS capacitors due to the lower parasitic characteristics that MEMS capacitors exhibit, for example the lower effective resistances and lower effective inductances, to thereby provide more precise and more effective control of power delivery from tester 110 to DUT 218. Simulations have shown that placing MEMS capacitors proximate to probe tips 216 of probes 214 may reduce voltage droop from 30% down to 24% of the applied voltage for current generation of processors, although the scope of the invention is not limited in this respect. Furthermore, the invention described here can be used to place capacitors at the tips of input and output (I/O) signal probes in order to enable testing of high speed circuits.

Referring now to FIG. 6, a diagram of a space transformer having an array of probes thereon in accordance with one embodiment of the present invention will be discussed. The array of probes 214 may be soldered, brazed, or otherwise connected to space transformer 212 in some other fashion. It is not necessary that probes 214 be attached to space transformer 212. It is sufficient that probes 214 are held in place in an appropriate location in preparation for attachment of capacitor 510. Solder paste 512 may be applied to the ends of probes 214 for attachment of capacitor 510 to probes 214, although the scope of the invention is not limited in this respect.

Referring now to FIG. 7, a diagram of a semiconductor wafer having MEMS capacitors formed thereon will be discussed. Capacitors 510, which in FIG. 7 are shown as MEMS capacitors, may be formed in an array on a silicon wafer 710 and manufactured using a standard semiconductor process, although the scope of the invention is not limited in this respect. Further detail of a suitable MEMS capacitor is shown in and described with respect to FIG. 11.

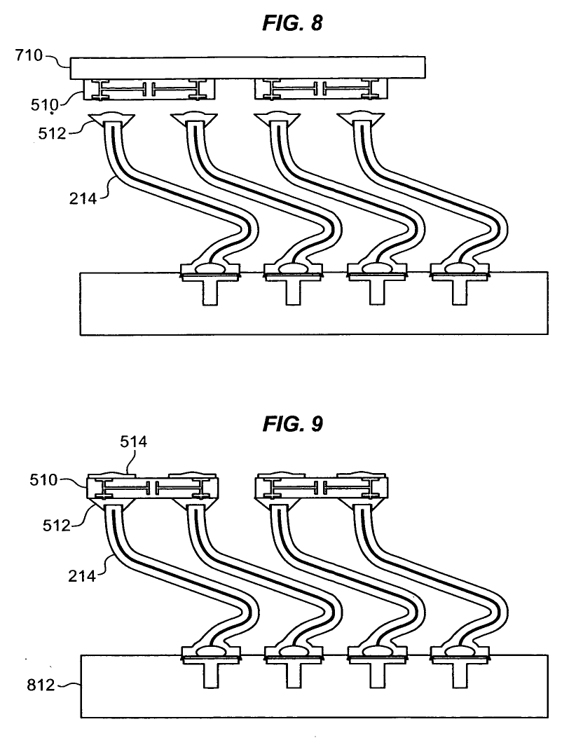

Referring now to FIG. 8, a diagram of a space transformer ready for connection of MEMS capacitors in accordance with an embodiment of the present invention will be discussed. As shown in FIG. 8, during attachment of capacitors 510 to probes 214, the wafer 710 holding capacitors 510 may be inverted and aligned with probes 214. Once aligned, capacitors 510 may be attached to probes 214, for example by being soldered at locations of solder paste 510, and then may be singulated from wafer 710 through a mechanical or chemical process, for example etching, although the scope of the invention is not limited in this respect. Although FIG. 8 shows single capacitors 510 connected between two adjacent probes 214, the scope of the invention is not limited in this respect. Alternatively, a single capacitor 510 may couple three or more of probes 214 via the capacitor 510. Various other arrangements of capacitors 510 to probes 214 are contemplated and within the scope of the present invention.

Referring now to FIG. 9, a diagram of a space transformer in a state after attachment of a MEMS capacitor to the probes in accordance with one embodiment of the present invention will be discussed. As shown in FIG. 9, after attachment of capacitors 510 as shown in FIG. 8, another layer of solder paste 514 may be added to capacitors 510 in preparation of attachment of probe tips 216 to capacitors 510, although the scope of the invention is not limited in this respect.

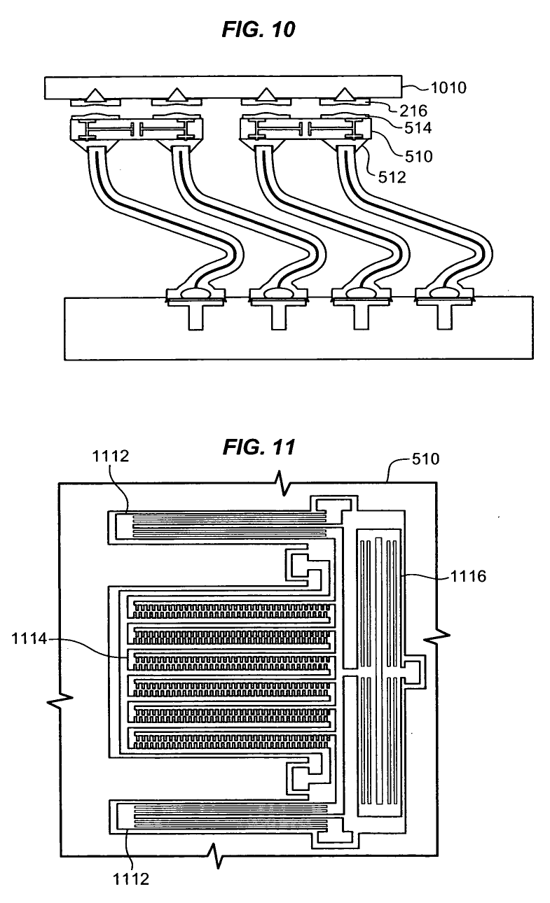

Referring now to FIG. 10, a diagram of a space transformer during attachment of the probe tips in accordance with an embodiment of the present invention will be discussed. Probe tips 216 may be manufactured on a silicon wafer 1010 or the like using a standard semiconductor manufacturing process which may be similar or identical to the process by which MEMS capacitors 510 are manufactured as shown in and described with respect to FIG. 7, although the scope of the invention is not limited in this respect. Wafer 1010 having probe tips 216 thereon may be positioned as shown in FIG. 10, and probe tips 216 may be aligned to the capacitors 510, for example so that probe tips 216 may be aligned with the locations of solder paste 514. Probe tips 216 then may be attached to capacitors 10 and detached from the wafer 1010. A resulting space transformer 114 having capacitors 510 disposed at the ends of probes 214 at the probe tips 216 is shown in FIG. 5.

Referring now to FIG. 11, a diagram of a MEMS capacitor in accordance with one embodiment of the present invention will be discussed. In accordance with one embodiment of the invention, capacitors 510 may be MEMS capacitors. For example, the Carnegie Mellon University of Pittsburgh, Pa., U.S.A. and the Massachusetts Institute of Technology (MIT) of Cambridge, Mass., U.S.A. have demonstrated, manufactured and characterized MEMS capacitors that may be suitable for utilization as capacitors 510 in accordance with one or more embodiments of the present invention. FIG. 11 is a representation of a MEMS capacitor manufactured at the Carnegie Mellon University on a 350 nm CMOS process (A. Oz, et al, Carnegie Mellon University, The 12^{th} International Conference on Solid State Sensors, Actuators, and Microsystems, Boston, Jun. 8-12, 2003). Such a MEMS capacitor 510 may include actuators 1112, fingers 1114, and a latch mechanism 1116. Other similar MEMS capacitors may be suitable for utilization as capacitors 510 without departing from the scope of the present invention. Further information on MEMS capacitors may be found at the University of Hawaii, Manoa, Hi., U.S.A. (http://www-ee.eng.hawaii.edu)

Although the invention has been described with a certain degree of particularity, it should be recognized that elements thereof may be altered by persons skilled in the art without departing from the spirit and scope of the invention. It is believed that the sort interface unit having probe capacitors of the present invention and many of its attendant advantages will be understood by the forgoing description, and it will be apparent that various changes may be made in the form, construction and arrangement of the components thereof without departing from the scope and spirit of the invention or without sacrificing all of its material advantages, the form herein before described being merely an explanatory embodiment thereof, and further without providing substantial change thereto. It is the intention of the claims to encompass and include such changes.

What is claimed is:

1. An apparatus, comprising:
a printed circuit board having one or more electrical traces to couple to a wafer tester;
a space transformer having at least two or more probes to couple the one or more electrical traces of the printed circuit board to a circuit formed on a wafer to be tested by the tester; and
a capacitor attached to at least two or more probes to capacitively couple at least two or more probes.

2. An apparatus as claimed in claim 1, wherein the capacitor is a micro-electromechanical system (MEMS) capacitor.

3. An apparatus as claimed in claim 1, wherein the capacitor is disposed at an end of the at least two or more probes, at the end near the DUT when the DUT is tested.

4. An apparatus as claimed in claim 1, the at least two or more probes having a probe tip disposed at an end of the at least two or more probes, at the end near the DUT when the DUT is tested.

5. An apparatus as claimed in claim 1, with at least two or more probes having a probe tip disposed at an end of the at least two or more probes, at the end near the DUT when the DUT is tested, wherein the capacitor is coupled to the probe tip of at least two of the at least two or more probes.

6. An apparatus as claimed in claim 1, further comprising a ball grid array to couple said space transformer to the at least one or more traces of said printed circuit board.

7. An apparatus as claimed in claim 1, further comprising an interposer to couple said space transformer to the at least one or more traces of said printed circuit board.

8. An apparatus as claimed in claim 1, wherein said capacitor has a value selected based on an electrical characteristic of the circuit on the DUT.

9. An apparatus as claimed in claim 1, wherein said capacitor has a value selected based on an electrical characteristic of the circuit on the DUT, the electrical characteristic being at least one of power, current, voltage, or operational frequency.

10. An apparatus as claimed in claim 1, wherein said capacitor has a higher value when said circuit has a higher valued electrical characteristic, and has a lower value when said circuit has a lower valued electrical characteristic.

11. A method, comprising:
placing an array of probes on a space transformer;
positioning an array of micro-electromechanical system (MEMS) capacitors disposed on a wafer in alignment with the array of probes;
attaching the array of MEMS capacitors to the array of probes; and
removing the wafer from the capacitors to leave selected MEMS capacitors of the array of capacitors attached to respective probes of the array of probes.

12. A method as claimed in claim 11, wherein probes of the array of probes are attached to the space transformer via soldering.

13. A method as claimed in claim 11, wherein probes of the array of probes are attached to the space transformer via brazing.

14. A method as claimed in claim 11, further comprising applying solder paste to ends of probes of the array of probes for soldering MEMS capacitors of the array of MEMS capacitors to probes of the array of probes.

15. A method as claimed in claim 11, further comprising attaching positioning an array of probe tips disposed on another wafer in alignment with the array of MEMS capacitors, and removing the other wafer from the probe tips to leave probe tips of the array of probe tips attached to MEMS capacitors of the array of MEMS capacitors.

16. A method as claimed in claim 11, further comprising applying solder paste to MEMS capacitors of the array of MEMS capacitors for soldering probe tips to the MEMS capacitors.

17. An apparatus, comprising:
a wafer tester to test a circuit disposed on a wafer; and
a sort interface unit coupled to an end of said wafer tester, wherein said sort interface unit comprises:
a printed circuit board having one or more electrical traces to couple to a wafer tester;
a space transformer having at least two or more probes to couple the one or more electrical traces of the printed circuit board to a circuit formed on a wafer to be tested by the tester, wherein said space transformer couples to said printed circuit board via a ball grid array; and
a micro-electromechanical system (MEMS) capacitor attached to the at least two or more probes to capacitively couple at least two of the at least two or more probes.

18. An apparatus as claimed in claim 17, wherein the MEMS capacitor is disposed at an end of the at least two of the at least two or more probes, at the end near the DUT when the DUT is tested.

19. An apparatus as claimed in claim 17, the at least two or more probes having a probe tip disposed at an end of the at least two or more probes, at the end near the DUT when the DUT is tested.

20. An apparatus as claimed in claim 17, the at least two or more probes having a probe tip disposed at an end of the at least two or more probes, at the end near the DUT when the DUT is tested, wherein said MEMS capacitor is coupled to the probe tip of at least two of the at least two or more probes.

22. An apparatus as claimed in claim 17, wherein said MEMS capacitor has a value selected based on an electrical characteristic of the circuit on the DUT.

23. An apparatus as claimed in claim 17, wherein said MEMS capacitor has a value selected based on an electrical characteristic of the circuit on the DUT, the electrical characteristic being at least one of power, current, voltage, or operational frequency.

24. An apparatus as claimed in claim 17, wherein said MEMS capacitor has a higher value when said circuit has a higher valued electrical characteristic, and has a lower value when said circuit has a lower valued electrical characteristic.

25. An apparatus, comprising:
a printed circuit board having one or more electrical traces to couple to a wafer tester;
a space transformer having at least two or more probes to couple the one or more electrical traces of the printed circuit board to a circuit formed on a wafer to be tested by the tester; and
a first micro-electromechanical system (MEMS) capacitor attached to a first pair of the at least two or more probes, and a second MEMS capacitor attached to a second pair to the at least two or more probes, the first MEMS capacitor having a higher value than a value of the second MEMS capacitor wherein the first pair of the at least two or more probes couples to a higher power circuit on the wafer, and the second pair of the at least two or more probes couples to a lower power circuit on the wafer, when the tester tests the wafer.

26. An apparatus as claimed in claim 25, wherein at least one of the first and second MEMS capacitors is disposed at an end of the at least two of the at least two or more probes, at the end near the DUT when the DUT is tested.

27. An apparatus as claimed in claim 25, the at least two or more probes having a probe tip disposed at an end of the at least two or more probes, at the end near the DUT when the DUT is tested.

28. An apparatus as claimed in claim 1, the at least two or more probes having a probe tip disposed at an end of the at least two or more probes, at the end near the DUT when the DUT is tested, wherein at lest one of the first and second MEMS capacitors is coupled to the probe tip of at least two of the at least two or more probes.
